(19) United States
(12) Patent Application Publication
(10) Pub. No.: US 2026/0323911 A1
(43) Pub. Date: Oct. 15, 2026

(54) Memory Circuitry And Methods Used In Forming Memory Circuitry

(71) Applicant: Micron Technology, Inc., Boise, ID (US)

(72) Inventors: Darwin Franseda Fan, Boise, ID (US); Kangle Li, Boise, ID (US)

(73) Assignee: Micron Technology, Inc., Boise, ID (US)

(21) Appl. No.: 19/179,148

(22) Filed: Apr. 15, 2025

(51) Int. Cl. H10B 12/00

(52) U.S. Cl. CPC H10B 12/30; H10B 12/03; H10B 12/05

(57) ABSTRACT

Memory circuitry comprises vertically-alternating insulative tiers and memory-cell tiers. Memory cells in the memory cell tiers individually comprise a horizontal transistor, a capacitor, and part of a digitline. The capacitor comprises a capacitor electrode that is common to a plurality of the memory cells. The common capacitor electrode comprises a void-space in individual of the insulative tiers. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-5 are diagrammatic cross-sectional views of a portion of a construction in process in accordance with embodiments of the invention.

FIGS. 6-34 are diagrammatic sequential sectional and/or enlarged views of the construction of FIGS. 3-5, or portions thereof or alternate and/or additional embodiments, in process in accordance with some embodiments of the invention.

### DETAILED DESCRIPTION OF EXAMPLE EMBODIMENTS

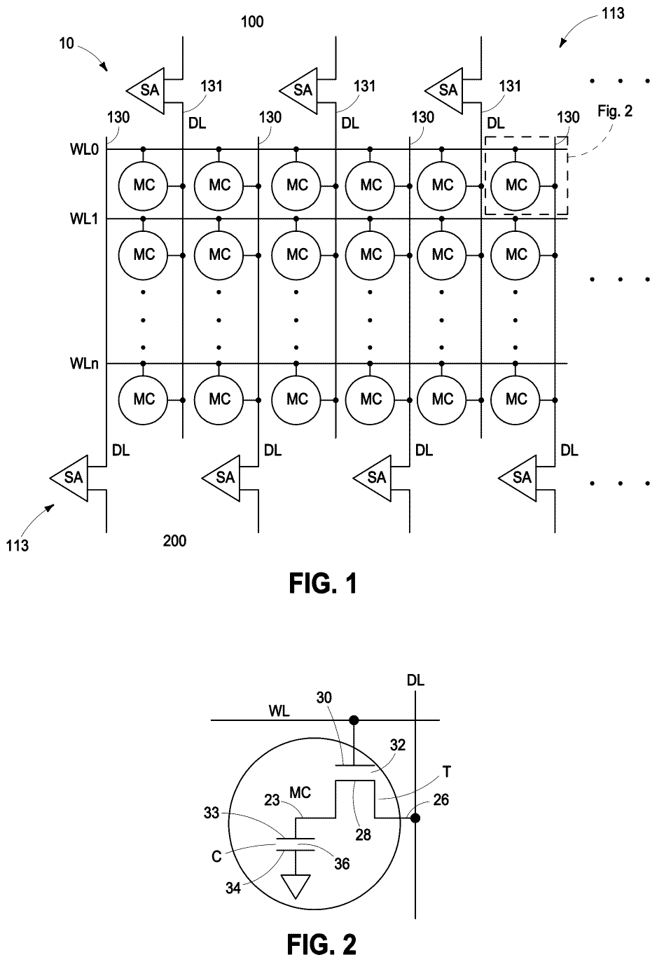

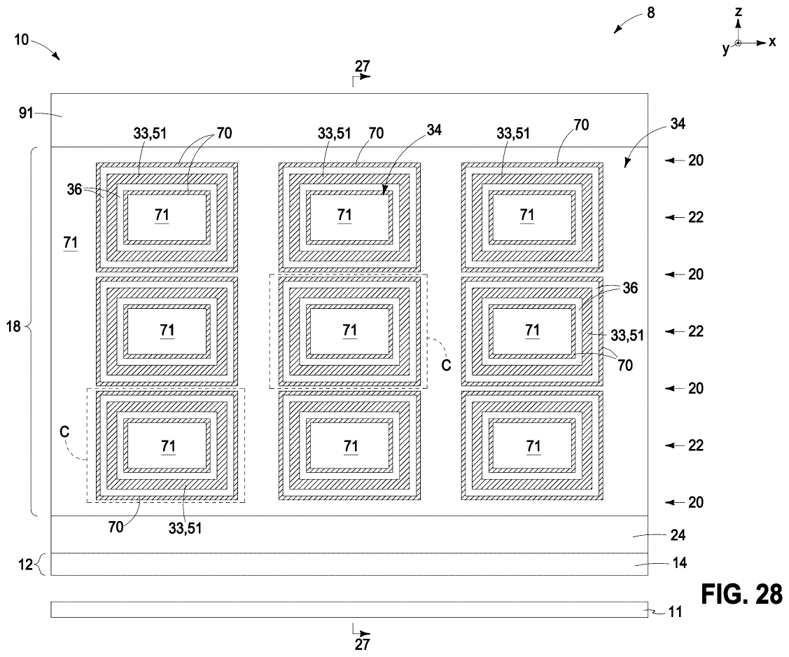

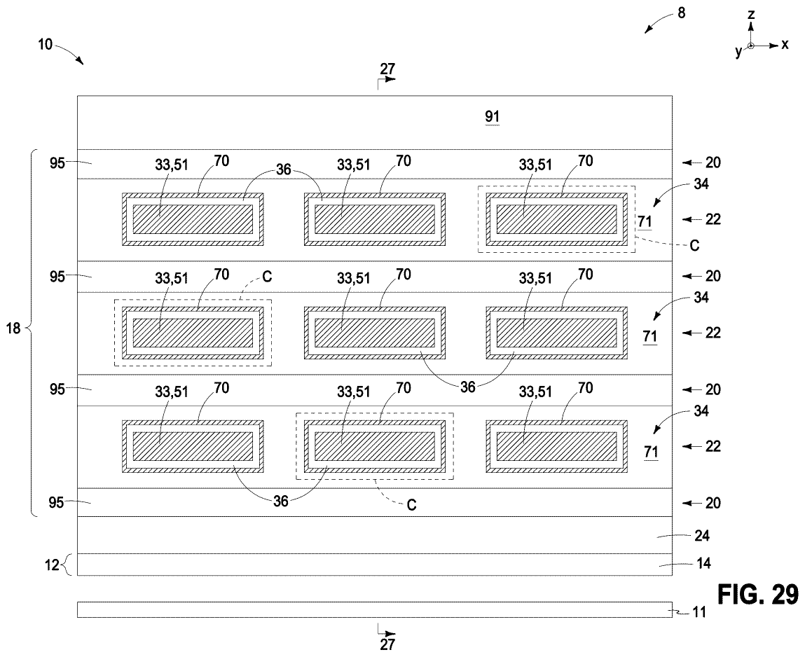

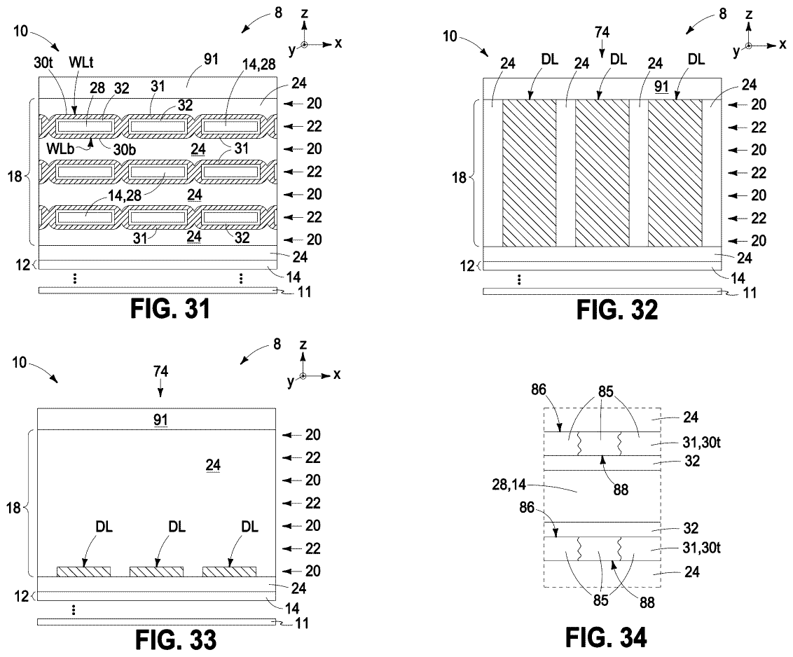

Embodiments of the invention encompass memory circuitry (e.g., DRAM) comprising vertically-stacked memory cells individually comprising a horizontal transistor and a capacitor electrically coupled therewith. Embodiments of the invention also encompass methods used in forming such memory circuitry. Example method embodiments are described with reference to FIGS. 1-34 to satisfy enablement and best mode requirements, although of course not all method steps are necessarily required in accordance with the invention which is only defined with required steps in individual of the accompanying claims.

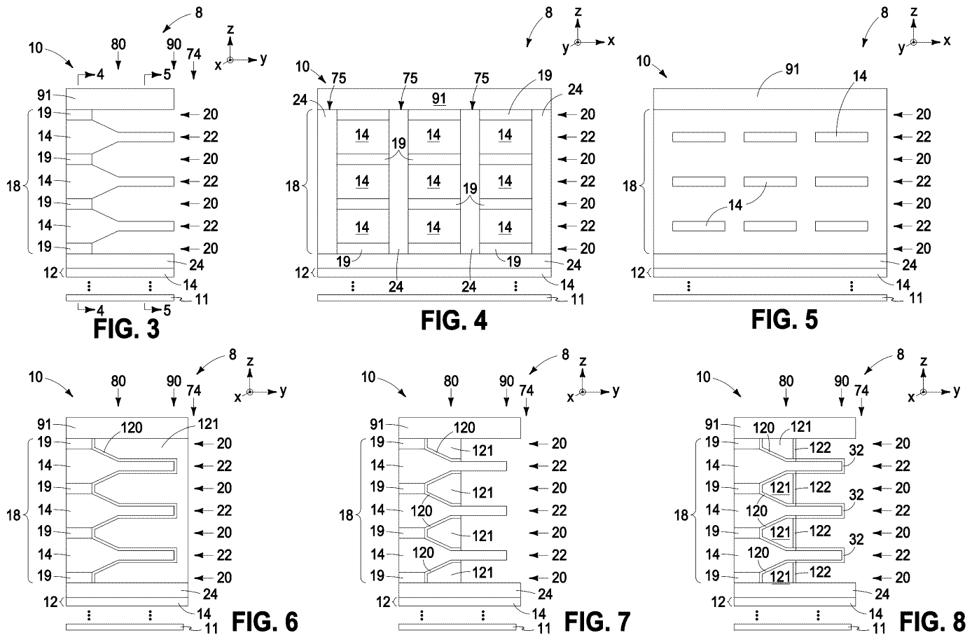

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+have the wordlines/access lines running horizontally and the digitlines/sense lines running vertically.

Referring to FIGS. 3-5, and in some embodiments, a construction 8 comprises an array or array area 10 that has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-5-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., comprising semiconductive material 14, such as elemental monocrystalline silicon) having insulative material 24 there-above (e.g., silicon dioxide).

A stack 18 has been formed above base substrate 11 and comprises vertically-alternating insulative tiers 20 and memory-cell tiers 22. Many more tiers 20 and 22 would be in stack 18 than shown. Memory-cell tiers 22 may not comprise memory cells initially and insulative tiers 20 may not comprise insulative material initially. Example memory-cell tiers 22 comprise semiconductive material 14 (e.g., elemental monocrystalline, epitaxial, and/or polycrystalline silicon and which may include one or more additional elements) and example insulative tiers 20 comprise silicon—germanium material 19 (e.g., Si₁₋ₓGeₓ [a semiconductive material] and which may include one or more additional elements). An example hardmask 91 (e.g., top and bottom silicon dioxide layers having a silicon nitride layer vertically there-between) is atop stack 18. In a finished memory-circuitry construction, memory cells (not-yet-shown) of the memory circuitry individually comprise a horizontal transistor (not-yet-shown), a capacitor (not-yet-shown), and part of a digitline (not-yet-shown). In some embodiments, the horizontal transistor comprises a gate having top and bottom gates (not-yet-shown) and may be considered as having a capacitor side (e.g., 80) and a digitline side (e.g., 90). Insulative tiers 20 comprise insulative material (not-yet-shown) in the finished memory-circuitry construction that is vertically between immediately-vertically-adjacent of the memory cells (there being no other such noun [memory cell] between those that are immediately-adjacent one another). Example insulative walls 75 (e.g., comprising insulative material 24) are shown and will separate the source/drain regions of immediately-x-direction-adjacent horizontal transistors in individual memory-cell tiers 22 in the finished construction.

In one example and as shown, a horizontally-elongated digitline trench 74 (e.g., horizontally elongated in an x-direction) has been formed vertically through stack 18 on digitline side 90. In this document, a digitline trench is a trench in which digitlines have been or will be formed. Through digitline trench 74, insulative walls 75 having been laterally etched back, silicon—germanium material 19 has been laterally etched back, and semiconductive material 14 has been vertically thinned (e.g., all by separate etchings).

Referring to FIG. 6, a protective liner of sacrificial material 120 (e.g., a low quality, low-temperature-deposited, silicon dioxide) has been formed within digitline trench 74, followed by depositing sacrificial material 121 thereover (e.g., silicon nitride). FIG. 7 shows lateral recessing of sacrificial materials 120 and 121 (e.g., by wet isotropic etching, with the etching of sacrificial material 120 being conducted selectively relative to semiconductor material 14).

Referring to FIG. 8, gate insulator 32 has been formed around semiconductive material 14. Such may comprise any suitable dielectric and/or ferroelectric material (e.g., one or more of high-k materials, silicon nitride, silicon dioxide, hafnium oxide, etc.). In one example where semiconductive material 14 is silicon, such may be oxidized to form gate insulator 32 to be a high quality, high-temperature-oxidized, silicon dioxide, and which may form silicon oxynitride 122 against a silicon nitride sacrificial material 121 as shown.

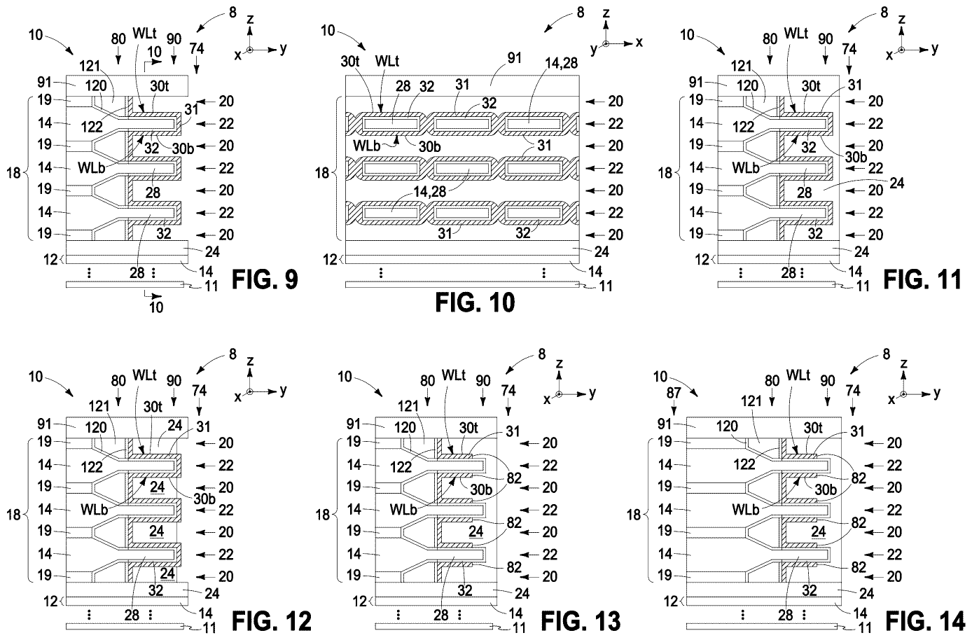

Referring to FIGS. 9 and 10, conductive material 31 (e.g., conductive metal material such as titanium nitride) of gates of the horizontal transistors being formed has been deposited from within digitline trench 74. Such will comprise a top gate 30t and a bottom gate 30b of the individual horizontal transistors being formed. Top gate 30t is part of one of a plurality of top horizontal conductive access lines WLt and bottom gate 30b is part of one of a plurality of bottom horizontal conductive access lines WLb. Top horizontal conductive access line WLt and bottom horizontal conductive access line WLb together directly electrically couple together multiple of the top and bottom gates of different ones of the horizontal transistors that are in the same memory-cell tier 22. Semiconductive material 14 is vertically between top gate 30t and bottom gate 30b and will comprise channel regions 28 of the horizontal transistors being formed. Top access line WLt and bottom access line WLb join together between immediately-horizontally-x-direction-adjacent channel regions 28/14 of the horizontal transistors being formed. In the described method example, lateral y-direction edges of gates 30* and access lines WL* have not yet been formed or defined (an * being used as a suffix to be inclusive of all such same-numerically-designated structures or portions thereof that may or may not have other suffixes).

Referring to FIG. 11, insulative material 24 of insulative tiers 20 that will remain in the finished memory-circuitry construction has been formed within digitline trench 74. FIG. 12 shows lateral etch-back of insulative material 24. FIG. 13 shows etch-back of conductive material 31 to form digitline-side edges 82 of gates 30*/access lines WL*, followed by forming more insulative material 24 within digitline trench 74.

Referring to FIG. 14, a horizontally-elongated (in the x-direction) capacitor trench 87 has been formed through stack 18 on capacitor side 80. In this document, a capacitor trench is a trench in or from which capacitors have been or will be formed.

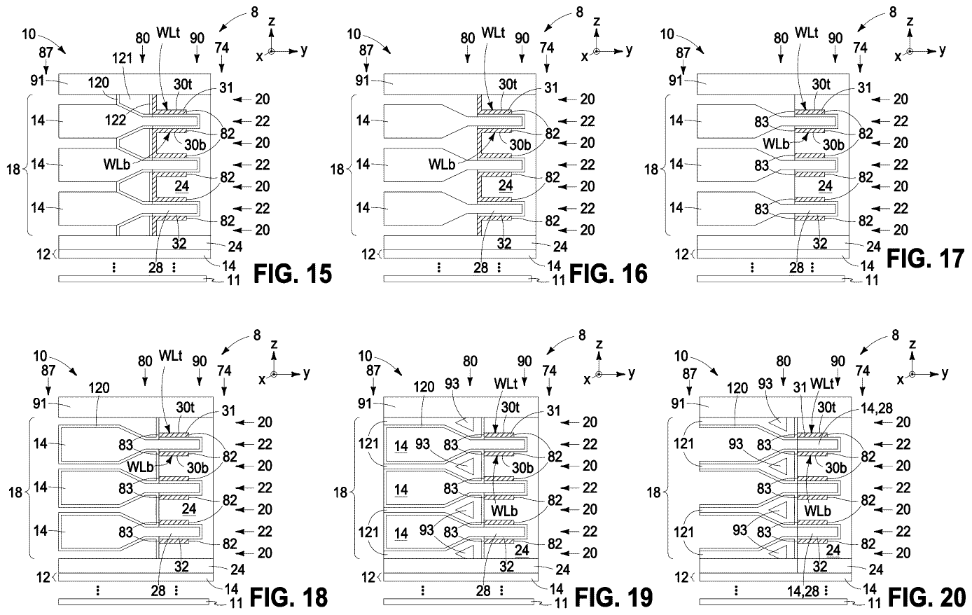

Referring to FIG. 15, silicon-germanium material 19 (no longer shown) has been removed from insulative tiers 20 through capacitor trench 87 in the depicted cross-section.

Referring to FIG. 16, several processing steps have occurred. Sacrificial material 120 (no longer shown) was etched to expose sacrificial material 121 (no longer shown). Then, sacrificial material 121 was etched selectively relative to sacrificial material 120 and silicon oxynitride 122 (no longer shown). This was followed by etching away remaining sacrificial material 120, followed by etching silicon oxynitride 122 selectively relative to gate insulator 32.

Referring to FIG. 17, conductive material 31 has been isotropically etched, thereby defining gate 30*/access line WL* side edge 83 which is laterally opposing to side edge 82 shown formed in FIG. 11, thus forming completed y-direction outlines of top gate 30t/top access line WLt and bottom gate 30b/bottom access line WLb of the horizontal transistors being formed. In one embodiment and as shown, semiconductive material 14 that is vertically between top gate 30t and bottom gate 30b extends laterally beyond laterally opposing side edges 82, 83 of each of top gate 30t and bottom gate 30b.

Referring to FIG. 18, another liner of sacrificial material 120 has been formed through and from within capacitor trench 87. FIG. 19 shows the forming of more sacrificial material 121 in capacitor trench 87, followed by lateral recessing thereof to expose sacrificial material 121 within capacitor trench 87 as shown. Such may form void-space 93 in insulative tiers 20 as shown (e.g., elongated horizontally in the x-direction).

Referring to FIG. 20, semiconductive material 14 has been etched back from capacitor trench 87 as shown (e.g., selectively relative to sacrificial materials 120 and 121). In one embodiment and as shown, all of semiconductive material 14 that extends laterally beyond one of laterally opposing side edges 82, 83 (e.g., side edge 83 as shown) has been removed (e.g., by the etching of semiconductive material 14 laterally as shown).

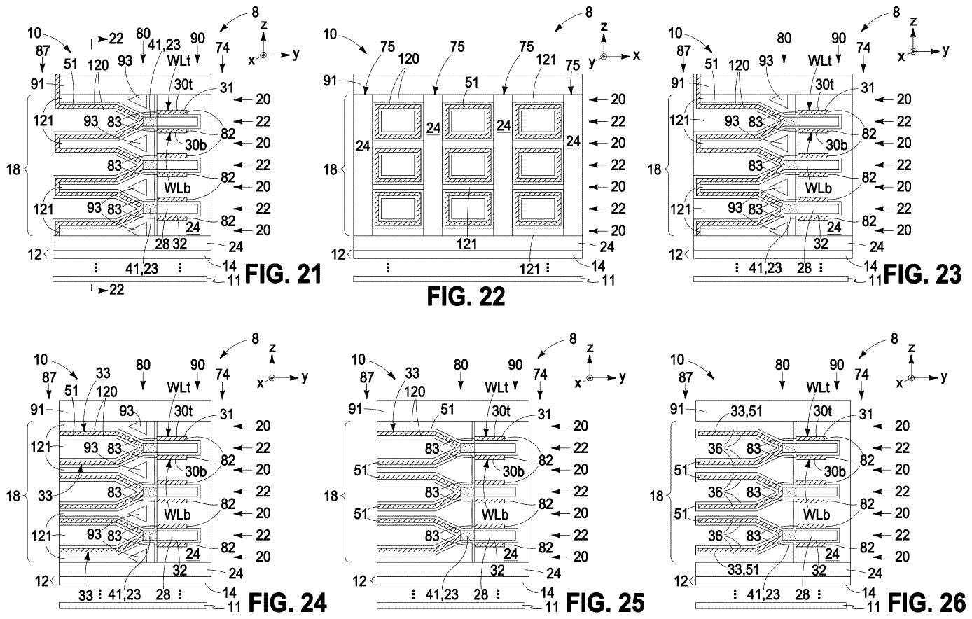

Referring to FIGS. 21 and 22, and where semiconductive material 14 was previously removed from extending beyond laterally opposing side edge 83, such removed semiconductive material has been replaced with semiconductor material 41 (e.g., which may be the same or different composition from that of semiconductive material 14). Semiconductor material 41 has been conductively-doped through capacitor trench 87 (e.g., by gas diffusion doping), or during its deposition, to form or comprise one source/drain region 23 (e.g., capacitor-side first source/drain region 23) of the individual horizontal transistors in the finished memory-circuitry construction. FIGS. 21 and 22 also show subsequent formation of storage-node capacitor electrode material 51 directly against source/drain region 23, followed by formation of another protective liner of sacrificial material 120 there-over.

Referring to FIG. 23, more sacrificial material 121 has been formed and laterally recessed back (e.g., by etching) to expose sacrificial material 120. FIG. 24 shows removing of sacrificial material 120 from capacitor trench 87 to expose capacitor electrode material 51, followed by etching such material to form isolated first capacitor electrodes 33 of the capacitors being formed.

Referring to FIG. 25, remaining sacrificial material 121 (no longer shown) has been removed (e.g., by etching). FIG. 26 shows subsequent formation of a capacitor insulator 36 (e.g., dielectric and/or ferroelectric) as part of the capacitors being formed.

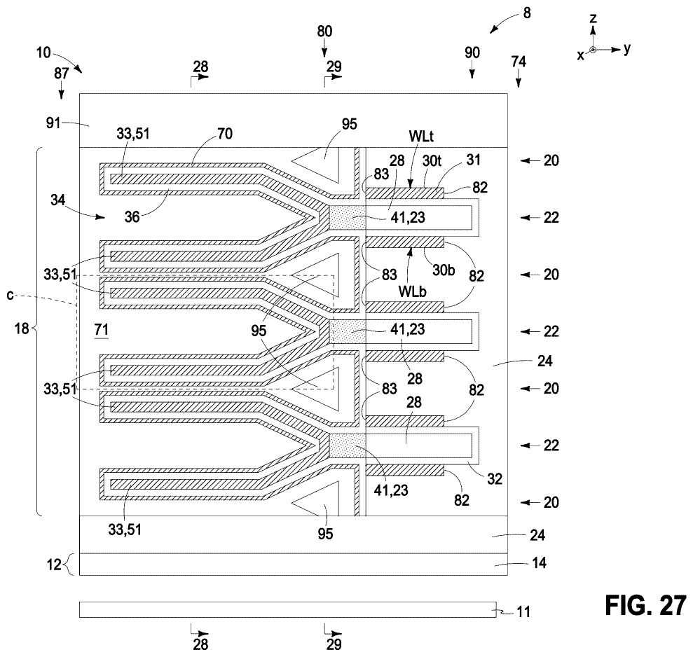

FIGS. 27-29 show subsequent completion in the formation of capacitors C which individually comprise first capacitor electrode 33 (e.g., a storage node electrode), a second capacitor electrode 34 (e.g., comprising conductive metal material 70 and conductively-doped polysilicon 71), and capacitor insulator 36 there-between. Example second capacitor electrode 34 is common to a plurality (not necessarily all) of the memory cells being formed (e.g., directly electrically coupled with and/or comprising a part thereof). In one such embodiment, common second capacitor electrode 34 has been formed to comprise a void-space 95 in individual insulative tiers 20 that will be in the finished memory-circuitry construction (not-yet-completed).

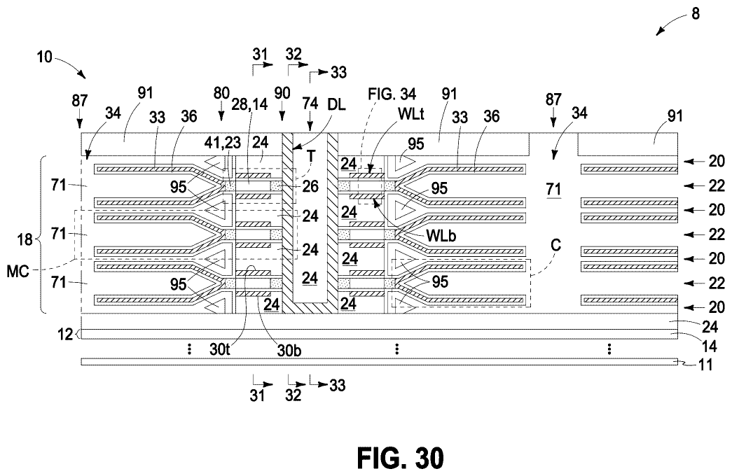

Referring to FIGS. 30-33, insulative material 24 that was in digitline trench 74 was removed, followed by removal of gate insulator material 32 from the digitline-side ends of remaining semiconductive material 14. Then, such exposed digitline-side ends have been conductively doped through digitline trench 74 (e.g., by gas diffusion doping) to form digitline-side second source/drain regions 26, thus forming individual horizontal transistors T. Digitlines DL were subsequently formed in digitline trench 74, with individual digitlines DL being directly against second source/drain regions 26. More insulative material 24 was formed in digitline trench 74, before or after forming digitlines DL, to isolate digitlines DL in the horizontal x-direction. Accordingly, individual memory cells MC have been formed that individually comprise a horizontal transistor T, a capacitor C, and part of a digitline DL in a finished memory-circuitry construction.

In one embodiment, a method used in forming memory circuitry (e.g., 8) comprises forming vertically-alternating insulative tiers (e.g., 20) and memory-cell tiers (e.g., 22). Memory cells (e.g., MC) of the memory-cell tiers individually comprise a horizontal transistor (e.g., T), a capacitor (e.g., C), and part of a digitline (e.g., DL) in a finished memory-circuitry construction (e.g., 8 in FIGS. 30-33 where memory-cell constructions MC have been completed). The insulative tiers comprise insulative material (e.g., 24) in the finished memory-circuitry construction that is vertically between immediately-vertically-adjacent of the memory cells. All conductive material (e.g., 31) of gates (e.g., 30*) of the horizontal transistors is formed (e.g., FIGS. 9 and 10) before forming at least a majority (i.e., greater than 50% up to and including 100%) of all of the insulative material that is vertically between the immediately-vertically-adjacent memory cells in the finished memory-circuitry construction. In one such embodiment and as shown, all of the insulative material that is vertically between the immediately-vertically-adjacent memory cells in the finished memory-circuitry construction is formed after forming all of the conductive material of the gates. In another one such embodiment and as shown, the capacitor is formed before the digitline. Any other attribute(s) or aspect(s) as shown and/or described herein with respect to other embodiments may be used.

In one embodiment, a method used in forming memory circuitry (e.g., 8) comprises forming vertically-alternating insulative tiers (e.g., 20) and memory-cell tiers (e.g., 22). Memory cells (e.g., MC) of the memory-cell tiers individually comprise a horizontal transistor (e.g., T), a capacitor (e.g., C), and part of a digitline (e.g., DL) in a finished memory-circuitry construction (e.g., 8 in FIGS. 30-33 where memory-cell constructions MC have been completed). A capacitor electrode (e.g., 34) of the capacitor is formed to be common to a plurality of the memory cells. The common capacitor electrode comprises a void-space (e.g., 95, and horizontally elongated in the x-direction) in individual of the insulative tiers in the finished memory-circuitry construction. In one embodiment and as shown, the void-space in the finished memory-circuitry construction is taller more proximate the gate of the horizontal transistor than distal therefrom. In one embodiment and as shown, the void-space in the finished memory-circuitry construction vertically spans at least a majority of individual of the insulative tiers. Any other attribute(s) or aspect(s) as shown and/or described herein with respect to other embodiments may be used.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 8) comprises vertically-alternating insulative tiers (e.g., 20) and memory-cell tiers (e.g., 22). Memory cells (e.g., MC) in the memory cell tiers individually comprise a horizontal transistor (e.g., T), a capacitor (e.g., C), and part of a digitline (e.g., DL). The capacitor comprises a capacitor electrode (e.g., 34) that is common to a plurality of the memory cells. The common capacitor electrode comprises a void-space (e.g., 95, and horizontally elongated in the x-direction, such as through the array) in individual of the insulative tiers. In one such embodiment and as shown, the void-space is taller more proximate the gate of the horizontal transistor than distal therefrom. In another one such embodiment and as shown, the void-space vertically spans at least a majority of individual of the insulative tiers. In another one such embodiment and as shown, the capacitor comprises a storage node electrode that comprises a sideways container shape. Any other attribute(s) or aspect(s) as shown and/or described herein with respect to other embodiments may be used.

In one embodiment, memory circuitry (e.g., 8) comprises vertically-alternating insulative tiers (e.g., 20) and memory-cell tiers (e.g., 22). Memory cells (e.g., MC) in the memory cell tiers individually comprise a horizontal transistor (e.g., T), a capacitor (e.g., C), and part of a digitline (e.g., DL). The horizontal transistor comprises a gate (e.g., 30*) comprising a top gate (e.g., 30t) and a bottom gate (e.g., 30b). Each of the top and bottom gates has crystal grains (e.g., 85, in FIG. 34). At least some of the crystal grains individually extend continuously from top (e.g., 86) to bottom (e.g., 88) of individual of the top and bottom gates. In some embodiments, the at least some is more than 25%, less than 100%, no more than 80%, and/or no less than 60%.

Any other attribute(s) or aspect(s) as shown and/or described herein with respect to other embodiments may be used.

In prior processes, a void-space or seam (elongated in the x-direction) may form about midway in the vertical thickness of each of the top and bottom gates. Such typically results from atomic layer deposition or chemical vapor deposition of the conductive material of the individual gates depositing from both of the gate insulator surface in the memory-cell tier and the surface of the insulative material of the insulative tier, with the space there-between defining the vertical thickness of the respective gate that is being formed. The seam and/or void-space form(s) when the conductive material being deposited from these two surfaces meet. When such conductive material is formed before forming the insulative material of the insulative tiers, such deposition is only from the gate insulator surface, with time of deposition instead largely determining final gate thickness and seam and/or void-space formation may be precluded. Such may also result in single crystal grains extending from top to bottom of the gates and may thus increase conductivity.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of a vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming vertically-alternating insulative tiers and memory-cell tiers. Memory cells of the memory-cell tiers individually comprise a horizontal transistor, a capacitor, and part of a digitline in a finished memory-circuitry construction. The insulative tiers comprise insulative material in the finished memory-circuitry construction that is vertically between immediately-vertically-adjacent of the memory cells. All conductive material of gates of the horizontal transistors is formed before forming at least a majority of all of the insulative material that is vertically between the immediately-vertically-adjacent memory cells in the finished memory-circuitry construction.

In some embodiments, a method used in forming memory circuitry comprises forming vertically-alternating insulative tiers and memory-cell tiers. Memory cells of the memory-cell tiers individually comprise a horizontal transistor, a capacitor, and part of a digitline in a finished memory-circuitry construction. Top and bottom gates of individual of the horizontal transistors are formed. Semiconductive material is vertically between the top and bottom gates and extends laterally beyond laterally opposing side edges of each of the top and bottom gates. All of the semiconductive material that is extending laterally beyond one of the laterally opposing side edges of each of the top and bottom gates is removed. The removed semiconductive material is replaced with semiconductor material that comprises one source/drain region of the individual horizontal transistors in the finished memory-circuitry construction.

In some embodiments, a method used in forming memory circuitry comprises forming vertically-alternating insulative tiers and memory-cell tiers. Memory cells of the memory-cell tiers individually comprise a horizontal transistor, a capacitor, and part of a digitline in a finished memory-circuitry construction. A capacitor electrode of the capacitor is formed to be common to a plurality of the memory cells. The common capacitor electrode comprises a void-space in individual of the insulative tiers in the finished memory-circuitry construction.

In some embodiments, a method used in forming memory circuitry comprises forming vertically-alternating insulative tiers and memory-cell tiers. Memory cells of the memory-cell tiers individually comprise a horizontal transistor, a capacitor, and part of a digitline in a finished memory-circuitry construction. The insulative tiers comprise insulative material in the finished memory-circuitry construction that is vertically between immediately-vertically-adjacent of the memory cells. Top and bottom gates of individual of the horizontal transistors are formed. Semiconductive material is vertically between the top and bottom gates and extends laterally beyond laterally opposing side edges of each of the top and bottom gates. All conductive material of the top and bottom gates is formed before forming at least a majority of all of the insulative material that is vertically between the immediately-vertically-adjacent memory cells in the finished memory-circuitry construction. Each of the top and bottom gates has crystal grains. At least some of the crystal grains individually extend continuously from top to bottom of individual of the top and bottom gates. All of the semiconductive material that is extending laterally beyond one of the laterally opposing side edges of each of the top and bottom gates is removed. The removed semiconductive material is replaced with semiconductor material that comprises one source/drain region of the individual horizontal transistors in the finished memory-circuitry construction. A capacitor electrode of the capacitor is formed to be common to a plurality of the memory cells. The common capacitor electrode comprises a void-space in individual of the insulative tiers in the finished memory-circuitry construction.

In some embodiments, memory circuitry comprises vertically-alternating insulative tiers and memory-cell tiers. Memory cells in the memory cell tiers individually comprise a horizontal transistor, a capacitor, and part of a digitline. The capacitor comprises a capacitor electrode that is common to a plurality of the memory cells. The common capacitor electrode comprises a void-space in individual of the insulative tiers.

In some embodiments, memory circuitry comprises vertically-alternating insulative tiers and memory-cell tiers. Memory cells in the memory cell tiers individually comprise a horizontal transistor, a capacitor, and part of a digitline. The horizontal transistor comprises a gate. The gate comprises a top gate and a bottom gate. Each of the top and bottom gates has crystal grains. At least some of the crystal grains individually extend continuously from top to bottom of individual of the top and bottom gates.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, the method comprising:
forming vertically-alternating insulative tiers and memory-cell tiers; memory cells of the memory-cell tiers individually comprising a horizontal transistor, a capacitor, and part of a digitline in a finished memory-circuitry construction; the insulative tiers comprising insulative material in the finished memory-circuitry construction that is vertically between immediately-vertically-adjacent of the memory cells; and
forming all conductive material of gates of the horizontal transistors before forming at least a majority of all of the insulative material that is vertically between the immediately-vertically-adjacent memory cells in the finished memory-circuitry construction.

2. The method of claim 1 comprising forming all of the insulative material that is vertically between the immediately-vertically-adjacent memory cells in the finished memory-circuitry construction after forming all of the conductive material of the gates.

3. The method of claim 1 comprising forming the capacitor before forming the digitline.

4. The method of claim 1 wherein the capacitor comprises a capacitor electrode that is common to a plurality of the memory cells; and
forming the common capacitor electrode to comprise a void-space in individual of the insulative tiers in the finished memory-circuitry construction.

5. The method of claim 4 wherein the void-space in the finished memory-circuitry construction is taller more proximate the gates than distal therefrom.

6. The method of claim 4 wherein the void-space in the finished memory-circuitry construction vertically spans at least a majority of individual of the insulative tiers.

7. The method of claim 1 wherein the gate comprises a top gate and a bottom gate, each of the top and bottom gates having crystal grains, at least some of the crystal grains individually extending continuously from top to bottom of individual of the top and bottom gates.

8. A method used in forming memory circuitry, the method comprising:
forming vertically-alternating insulative tiers and memory-cell tiers; memory cells of the memory-cell tiers individually comprising a horizontal transistor, a capacitor, and part of a digitline in a finished memory-circuitry construction;
forming top and bottom gates of individual of the horizontal transistors, semiconductive material being vertically between the top and bottom gates and extending laterally beyond laterally opposing side edges of each of the top and bottom gates;
removing all of the semiconductive material that is extending laterally beyond one of the laterally opposing side edges of each of the top and bottom gates; and
replacing the removed semiconductive material with semiconductor material that comprises one source/drain region of the individual horizontal transistors in the finished memory-circuitry construction.

9. The method of claim 8 forming the capacitor to be directly electrically coupled to the one source/drain region.

10. The method of claim 8 wherein,
the insulative tiers comprise insulative material in the finished memory-circuitry construction that is vertically between immediately-vertically-adjacent of the memory cells; and
forming all conductive material of the top and bottom gates before forming at least a majority of all of the insulative material that is vertically between the immediately-vertically-adjacent memory cells in the finished memory-circuitry construction.

11. A method used in forming memory circuitry, the method comprising:
forming vertically-alternating insulative tiers and memory-cell tiers; memory cells of the memory-cell tiers individually comprising a horizontal transistor, a capacitor, and part of a digitline in a finished memory-circuitry construction; and
forming a capacitor electrode of the capacitor to be common to a plurality of the memory cells, the common capacitor electrode comprising a void-space in individual of the insulative tiers in the finished memory-circuitry construction.

12. The method of claim 11 wherein the horizontal transistor comprises a gate, the void-space in the finished memory-circuitry construction being taller more proximate the gate than distal therefrom.

13. The method of claim 11 wherein the void-space in the finished memory-circuitry construction vertically spans at least a majority of individual of the insulative tiers.

14. The method of claim 13 wherein the horizontal transistor comprises a gate, the void-space in the finished memory-circuitry construction being taller more proximate the gates than distal therefrom.

15. A method used in forming memory circuitry, the method comprising:
forming vertically-alternating insulative tiers and memory-cell tiers; memory cells of the memory-cell tiers individually comprising a horizontal transistor, a capacitor, and part of a digitline in a finished memory-circuitry construction; the insulative tiers comprising insulative material in the finished memory-circuitry construction that is vertically between immediately-vertically-adjacent of the memory cells;
forming top and bottom gates of individual of the horizontal transistors, semiconductive material being vertically between the top and bottom gates and extending laterally beyond laterally opposing side edges of each of the top and bottom gates, all conductive material of the top and bottom gates being formed before forming at least a majority of all of the insulative material that is vertically between the immediately-vertically-adjacent memory cells in the finished memory-circuitry construction, each of the top and bottom gates having crystal grains, at least some of the crystal grains individually extending continuously from top to bottom of individual of the top and bottom gates;
removing all of the semiconductive material that is extending laterally beyond one of the laterally opposing side edges of each of the top and bottom gates;
replacing the removed semiconductive material with semiconductor material that comprises one source/drain region of the individual horizontal transistors in the finished memory-circuitry construction; and
forming a capacitor electrode of the capacitor to be common to a plurality of the memory cells, the common capacitor electrode comprising a void-space in individual of the insulative tiers in the finished memory-circuitry construction.

16. Memory circuitry comprising:
vertically-alternating insulative tiers and memory-cell tiers, memory cells in the memory cell tiers individually comprising a horizontal transistor, a capacitor, and part of a digitline; and
the capacitor comprising a capacitor electrode that is common to a plurality of the memory cells, the common capacitor electrode comprising a void-space in individual of the insulative tiers.

17. The memory circuitry of claim 16 wherein the horizontal transistor comprises a gate, the void-space being taller more proximate the gate than distal therefrom.

18. The memory circuitry of claim 16 wherein the void-space vertically spans at least a majority of individual of the insulative tiers.

19. The memory circuitry of claim 16 wherein the void-space is horizontally elongated.

20. The memory circuitry of claim 16 wherein the capacitor comprises a storage node electrode that comprises a sideways container shape.

21. Memory circuitry comprising:
vertically-alternating insulative tiers and memory-cell tiers, memory cells in the memory cell tiers individually comprising a horizontal transistor, a capacitor, and part of a digitline; the horizontal transistor comprising a gate; and
the gate comprising a top gate and a bottom gate, each of the top and bottom gates having crystal grains, at least some of the crystal grains individually extending continuously from top to bottom of individual of the top and bottom gates.

22. The memory circuitry of claim 21 wherein the at least some is more than 25%.

23. The memory circuitry of claim 22 wherein the at least some is less than 100%.

24. The memory circuitry of claim 23 wherein the at least some is no more than 80%.

25. The memory circuitry of claim 24 wherein the at least some is no less than 60%.
